(19) United States
(12) Patent Application Publication
(10) Pub. No.: US 2026/0096314 A1
(43) Pub. Date: Apr. 2, 2026

(54) DISPLAY DEVICE AND ELECTRONIC DEVICE INCLUDING THE SAME

(71) Applicant: Samsung Display Co., LTD., Yongin-si (KR)

(72) Inventor: HYUNSEOK KO, Yongin-si (KR)

(21) Appl. No.: 19/269,285

(22) Filed: Jul. 15, 2025

(30) Foreign Application Priority Data
Sep. 30, 2024 (KR) 10-2024-0132643

(51) Int. Cl. H10K 59/131; H10H 29/49; H10K 102/00

(52) U.S. Cl. CPC H10K 59/131; H10H 29/49; H10K 2102/351

(57) ABSTRACT

A display device includes: a substrate including a display area and a pad area adjacent to the display area, a plurality of pixels arranged in the display area, a plurality of signal pads arranged in the pad area and spaced apart from each other, and a circuit board connected to the pad area. The circuit board includes: a base film and a plurality of lead electrodes arranged to be spaced apart from each other on the base film, connected one-to-one with the signal pads, and grouped into a plurality of leads groups having different thicknesses.

This application claims priority to Korean Patent Application No. 10-2024-0132643 under 35 U.S.C. § 119, filed on Sep. 30, 2024, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a display device which provides visual information and an electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

The display device may include a display panel and a circuit board for driving the display panel, and the display panel and the circuit board may be electrically connected through an anisotropic conductive film (ACF).

### SUMMARY

Embodiments provide a display device with reduced or minimized defects.

Embodiments provide an electronic device including the display device.

A display device according to embodiments of the present disclosure includes a substrate including a display area and a pad area adjacent to the display area, a plurality of pixels arranged in the display area, a plurality of signal pads arranged in the pad area and spaced apart from each other, and a circuit board connected to the pad area, where the circuit board includes: a base film and a plurality of lead electrodes arranged to be spaced apart from each other on the base film, connected one-to-one with the signal pads, and grouped into a plurality of leads groups having different thicknesses.

In an embodiment, the signal pads may be grouped into a plurality of pad groups, and a pitch between the signal pads included in one group of the pad groups may be different from a pitch between the signal pads included in another group of the pad groups.

In an embodiment, the lead groups may include a first lead group including first lead electrodes each having a first thickness, a second lead group including second lead electrodes each having a second thickness, a third lead group including third lead electrodes each having a third thickness, and a fourth lead group including fourth lead electrodes each having a fourth thickness. In such an embodiment, the first thickness, the second thickness, the third thickness, and the fourth thickness may be different from each other.

In an embodiment, the pad groups may include a first pad group including first signal pads spaced apart from each other at a first pitch and connected to the first lead group, a second pad group including second signal pads spaced apart from each other at a second pitch and connected to the second lead group, a third pad group including third signal pads spaced apart from each other at a third pitch and connected to the third lead group, and a fourth pad group including fourth signal pads spaced apart from each other at a fourth pitch and connected to the fourth lead group. In such an embodiment, the first pitch, the second pitch, the third pitch, and the fourth pitch may be different from each other.

In an embodiment, the fourth pitch may be greater than the second pitch, the second pitch may be greater than the first pitch, and the first pitch may be greater than the third pitch.

In an embodiment, the third thickness may be greater than the first thickness, the first thickness may be greater than the second thickness, and the second thickness may be greater than the fourth thickness.

In an embodiment, the first pad group may be located at a center portion of the pad area, the second pad group may be located between the first pad group and the third pad group, the third pad group may be located between the second pad group and the fourth pad group, and the fourth pad group may be located at an edge portion of the pad area.

In an embodiment, a signal applied to the first lead group, a signal applied to the second lead group, a signal applied to the third lead group, and a signal applied to the fourth lead group may be different from each other.

In an embodiment, each of the lead electrodes may include a first conductive layer arranged on the base film and including metal, a second conductive layer arranged on the first conductive layer and including metal, and a cover layer covering the first and second conductive layers and including gold (Au).

In an embodiment, the circuit board may further include a seed layer arranged to extend continuously between the base film and the lead electrodes and including metal.

A display device according to embodiments of the present disclosure includes a substrate including a display area and a pad area adjacent to the display area, a plurality of pixels arranged in the display area, a plurality of signal pads arranged in the pad area and spaced apart from each other, and a circuit board connected to the pad area, where the circuit board includes: a base film and a plurality of lead electrodes arranged to be spaced apart from each other on the base film, connected one-to-one with the signal pads, and grouped into a plurality of leads groups. In such an embodiment, a ratio of a width of a lower surface to a width of an upper surface of each of the lead electrodes included in one lead group of the lead groups may be different from a ratio of a width of a lower surface to a width of an upper surface of each of the lead electrodes included in another lead group of the lead groups.

In an embodiment, the signal pads may be grouped into a plurality of pad groups, and a pitch between the signal pads included in one pad group of the pad groups may be different from a pitch between the signal pads included in another pad group of the pad groups.

In an embodiment, the lead groups may include a first lead group including first lead electrodes, a second lead group including second lead electrodes, a third lead group including third lead electrodes, and a fourth lead group including fourth lead electrodes, a width of a first lower surface to a width of a first upper surface of each of the first lead electrodes may have a first ratio, a width of a second lower surface to a width of a second upper surface of each of the second lead electrodes may have a second ratio, a width of a third lower surface to a width of a third upper surface of each of the third lead electrodes may have a third ratio, and a width of a fourth lower surface to a width of a fourth upper surface of each of the fourth lead electrodes may have a fourth ratio. In such an embodiment, the first ratio, the second ratio, the third ratio, and the fourth ratio may have different from each other.

In an embodiment, the first lower surface, the second lower surface, the third lower surface, and the fourth lower surface may directly contact the base film.

In an embodiment, the pad groups may include a first pad group including first signal pads spaced apart from each other at a first pitch and connected to the first lead electrodes of the first lead group, respectively, a second pad group including second signal pads spaced apart from each other at a second pitch and connected to the second lead electrodes of the second lead group, respectively, a third pad group including third signal pads spaced apart from each other at a third pitch and connected to the third lead electrodes of the third lead group, respectively, and a fourth pad group including fourth signal pads spaced apart from each other at a fourth pitch and connected to the fourth lead electrodes of the fourth lead group, respectively. In such an embodiment, the first pitch, the second pitch, the third pitch, and the fourth pitch may be different from each other.

In an embodiment, the fourth pitch may be greater than the second pitch, the second pitch may be greater than the first pitch, and the first pitch may be greater than the third pitch.

In an embodiment, the fourth ratio may be greater than the second ratio, the second ratio is greater than the first ratio, and the first ratio is greater than the third ratio.

In an embodiment, the first pad group may be located at a center portion of the pad area, the second pad group may be located between the first pad group and the third pad group, the third pad group may be located between the second pad group and the fourth pad group, and the fourth pad group may be located at an edge portion of the pad area.

In an embodiment, each of the lead electrodes may include a seed pattern arranged on the base film and including metal, a conductive layer arranged on the seed pattern and including metal, and a cover layer covering the seed pattern and the conductive layer, an including gold (AU).

An electronic device according to embodiments of the present disclosure includes a display device and a processor which controls an operation of the display device, the display device includes: a substrate including a display area and a pad area adjacent to the display area, a plurality of pixels arranged in the display area, a plurality of signal pads arranged in the pad area and spaced apart from each other, and a circuit board connected to the pad area, where the circuit board includes: a base film and a plurality of lead electrodes arranged to be spaced apart from each other on the base film, connected one-to-one with the signal pads, and grouped into a plurality of leads groups having different thicknesses.

In a display device according to embodiments of the present disclosure, a pitch between signal pads included in one group of pad groups may be different from a pitch between the signal pads included in another group of the pad groups, and lead electrodes connected to the signal pads of a circuit board may have different thicknesses or may be grouped into a plurality of lead groups with different ratios of a width of a lower surface to a width of an upper surface. In such embodiments, the circuit board may be bonded to a pad area through an anisotropic conductive film. Accordingly, voids may not occur in the anisotropic conductive film, and an overall uniform bonding gap may be realized between the signal pads and the lead electrodes.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to embodiments of the present disclosure.

FIG. 2 is a cross-sectional view schematically illustrating the display device of FIG. 1.

FIG. 3 is a view illustrating a bent shape of the display device of FIG. 1.

FIG. 4 is a block diagram illustrating an external device electrically connected to the display device of FIG. 1.

FIG. 5 is a circuit diagram illustrating a circuit structure of a pixel in FIG. 1.

FIG. 6 is an enlarged cross-sectional view of area A of FIG. 2.

FIG. 7 is an enlarged plan view of a display panel and a driving integrated circuit bonded to the display panel arranged in a sub-area of FIG. 1.

FIG. 8 is a plan view illustrating the display panel and the driving integrated circuit of FIG. 7 and a circuit board bonded to the display panel.

FIG. 9 is a cross-sectional view illustrating an example of a cross-section taken along line I-I′ of FIG. 8.

FIGS. 10, 11, 12, 13, 14, 15, and 16 are cross-sectional views for explaining a method of the manufacturing the circuit board of FIGS. 8 and 9.

FIG. 17 is a cross-sectional view illustrating another example of a cross-section taken along line I-I′ of FIG. 8.

FIGS. 18, 19, 20, 21, and 22 are cross-sectional views for explaining a method of the manufacturing the circuit board of FIGS. 8 and 9.

FIG. 23 is a block diagram illustrating an electronic device according to embodiments of the present disclosure.

FIG. 24 is a schematic diagram illustrating an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device according to embodiments of the present disclosure will be explained in detail with reference to the accompanying drawings. The same reference numerals are used for the same components in the drawings, and any repetitive detailed descriptions of the same components will be omitted or simplified.

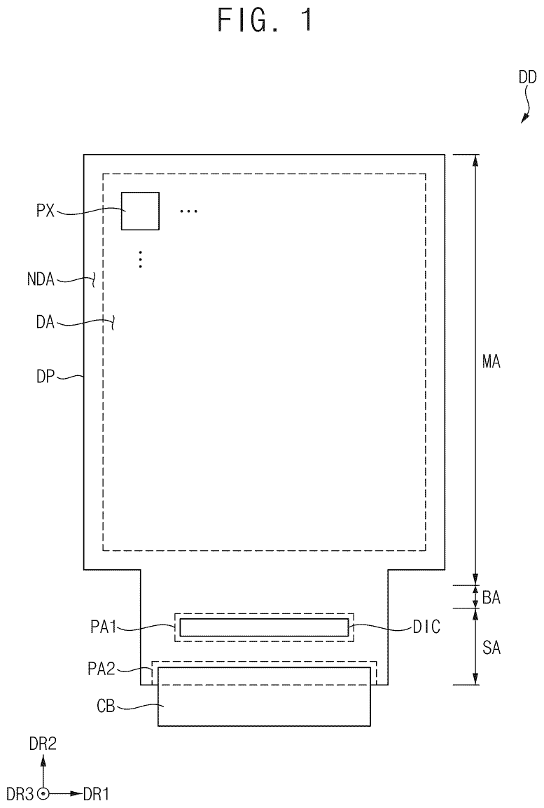

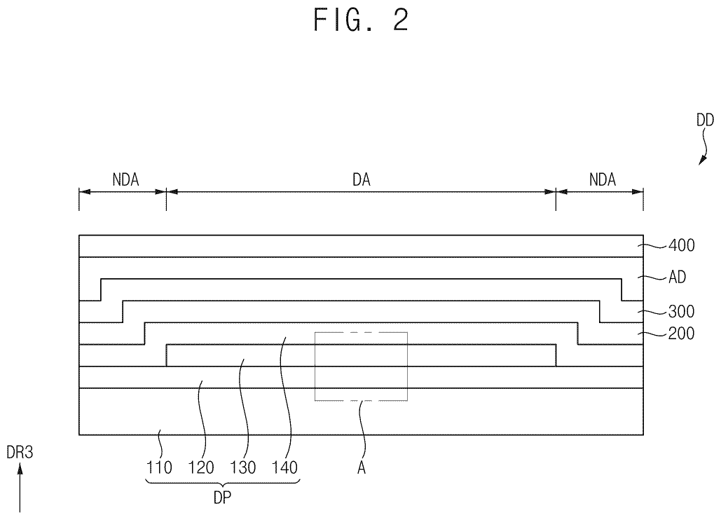

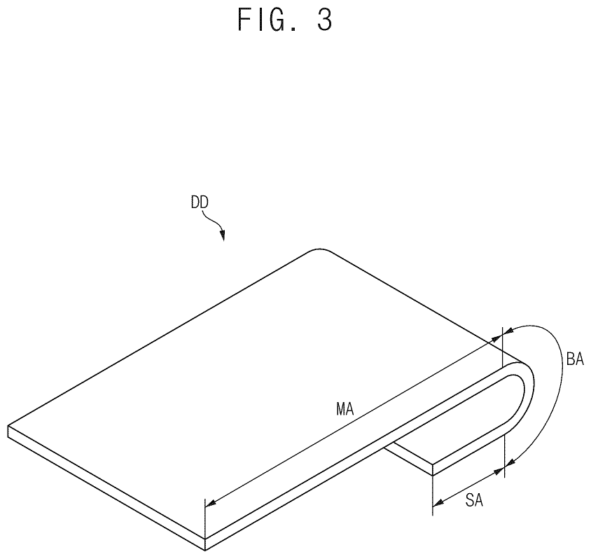

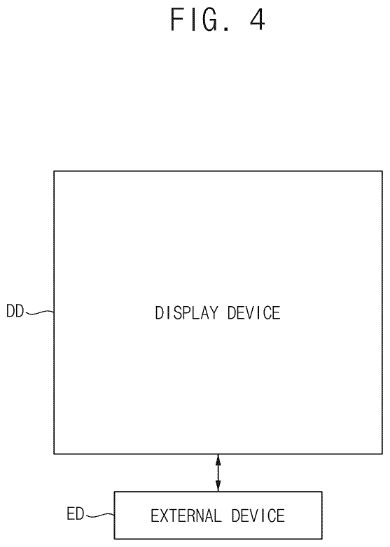

FIG. 1 is a plan view illustrating a display device according to embodiments of the present disclosure. FIG. 2 is a cross-sectional view schematically illustrating the display device of FIG. 1. FIG. 3 is a view illustrating a bent shape of the display device of FIG. 1. FIG. 4 is a block diagram illustrating an external device electrically connected to the display device of FIG. 1.

Referring to FIGS. 1, 3, and 4, the display device DD according to embodiments of the present disclosure may include a display panel DP, a driving integrated circuit DIC, and a circuit board CB.

The display device DD may have a rectangular planar shape (e.g., a rectangular planar shape with rounded corners). However, embodiments of the present disclosure are not necessarily limited thereto, and the display device DD may have various planar shapes.

The display panel DP may include a display area DA and a non-display area NDA. The display area DA may be an area that displays an image by generating light or adjusting the transmittance of light provided from an external light source. The non-display area NDA may be an area that does not display images. The non-display area NDA may be located around the display area DA. In an embodiment, for example, the non-display area NDA may entirely surround the display area DA.

The display panel DP may include a plurality of pixels PX arranged in the display area DA. The pixels PX may be arranged in a matrix form along a first direction DR1 and the second direction DR2 intersecting the first direction DR1. However, embodiments of the present disclosure are not necessarily limited to this, and the pixels PX may be arranged in various forms. No pixel may be disposed in the non-display area NDA.

Each of the pixels PX may include a driving element (e.g., a driving thin film transistor) which generates a driving current, and a light-emitting element (e.g., an organic light-emitting diode) which is electrically connected to the driving element and generates light based on the driving current. Accordingly, each of the pixels PX may emit light corresponding to the driving current generated therein. As the pixels PX emit light, the display area DA may display an image.

Lines connected to the pixels PX may be further arranged in the display area DA. In an embodiment, for example, the lines may include data lines, gate signal lines, power lines, or the like.

Drivers for driving the pixels PX may be arranged in the non-display area NDA. In an embodiment, for example, the drivers may include a gate driver, an emission driver, a power supply voltage generator, and a timing controller. The pixels PX may emit light based on signals received from the drivers.

The non-display area NDA may include a bending area BA and a sub-area SA. The sub-area SA may be located on one side of the display area DA. In an embodiment, for example, the sub-area SA may be located spaced apart from one side of the display area DA in a direction opposite to the second direction DR2.

The sub-area SA may include a first pad area PA1 and a second pad area PA2 spaced apart from each other in the second direction DR2. The first pad area PA1 may be located between the bending area BA and the second pad area PA2 in a plan view or when viewed in a third direction DR3. Here, the third direction DR3 may be a direction perpendicular to the first direction DR1 and the second direction DR2, or a thickness direction of the display panel DP. The second pad area PA2 may be located at an end of the sub-area SA.

The bending area BA may be located between the display area DA and the sub-area SA in the plan view. In an embodiment, as shown in FIG. 3, the bending area BA may be bent based on a bending axis extending in the first direction DR1. In such an embodiment, the sub-area SA may overlap a main area MA, which is defined as the display area DA and a portion of the non-display area NDA, in the plan view. That is, when the bending area BA is bent, the sub area SA may be located under the main area MA. The display device DD may be provided in a shape in which the bending area BA is bent about the bending axis.

The driving integrated circuit DIC may be bonded to the first pad area PA1 on the display panel DP. Accordingly, the driving integrated circuit DIC may be electrically connected to the display panel DP. In an embodiment, for example, the driving integrated circuit DIC may be bonded to the first pad area PA1 on the display panel DP through a thermal compression method.

The driving integrated circuit DIC may convert a digital data signal among the driving signals into an analog data signal and provide the converted data signal to the pixels PX. In an embodiment, for example, the driving integrated circuit DIC may be a data driver.

The circuit board CB may be bonded to the second pad area PA2 on the display panel DP. In an embodiment, for example, one end of the circuit board CB may be bonded to the second pad area PA2. Accordingly, the circuit board CB may be electrically connected to the display panel DP. The other end of the circuit board CB may be electrically connected to an external device ED. Signals, voltages, or the like generated from the external device ED may be provided to the driving integrated circuit DIC and the pixels PX through the circuit board CB.

In an embodiment, for example, the circuit board CB may be a flexible printed circuit board (FPCB), a printed circuit board (PCB), or a flexible flat cable (FFC).

In an embodiment, as shown in FIG. 4, the external device ED may be electrically connected to the display device DD. In an embodiment, for example, the external device ED may be electrically connected to the display device DD through the circuit board CB. The external device ED may generate a signal, voltage, or the like to display an image on the display device DD.

In an embodiment, as shown in FIG. 1, the driving integrated circuit DIC may be connected to the first pad area PA1 in a chip on plastic (COP) method or a chip on glass (COG) method, but embodiments of the present disclosure are not necessarily limited thereto. In another embodiment, for example, the driving integrated circuit (DIC) may be connected to the first pad area PA1 in a chip on film (COF) method.

Hereinafter, the stacked structure of an embodiment of the display device DD will be described with reference to FIG. 2.

Referring to FIG. 2, an embodiment of the display device DD may further include a touch sensor layer 200, an anti-reflection layer 300, an adhesive layer AD, and a window member WD.

The display panel DP may include a substrate 110, a pixel circuit layer 120 arranged on the substrate 110, a light emitting element layer 130 arranged on the pixel circuit layer 120, and an encapsulation layer 140 arranged on the light emitting element layer 130.

The substrate 110 may be a glass substrate, a metal substrate, or a polymer substrate. In an embodiment, the substrate 110 may be a flexible polymer substrate. However, embodiments of the present disclosure are not necessarily limited to this, and the substrate 110 may be an inorganic layer, an organic layer, or a composite material layer.

The pixel circuit layer 120 may include insulating layers, semiconductor elements (e.g., a transistor), conductive layers, signal lines, or the like.

The light emitting element layer 130 may include a light emitting element which generates light. In an embodiment, for example, the light emitting element may include an organic light emitting material, an inorganic light emitting material, an organic-inorganic light emitting material, a quantum dot, a micro light emitting diode (LED), or a nano LED.

The encapsulation layer 140 may protect the light emitting element layer 130 from foreign substances such as moisture and oxygen. In an embodiment, for example, the encapsulation layer 140 may include at least one inorganic layer and at least one organic layer. In an embodiment, the encapsulation layer 140 may have a stacked structure of a first inorganic layer, an organic layer, and a second inorganic layer.

The touch sensor layer 200 may be arranged on the display panel DP. The touch sensor layer 200 may detect an external input applied from outside. The external input may be a user's input. In an embodiment, for example, the user's input may include various types of external pressure, such as a part of the user's body, light, heat, pen, pressure, or the like. In an embodiment, for example, the touch sensor layer 200 may be formed directly on the display panel DP through a continuous process. Alternatively, the touch sensor layer 200 may be manufactured in a separate process and then attached to the display panel DP. Alternatively, the touch sensor layer 200 may be omitted.

The anti-reflection layer 300 may be arranged on the touch sensor layer 200. The anti-reflection layer 300 may reduce the reflectance of external light incident from the outside of the display device DD. The anti-reflection layer 300 may be formed on the touch sensor layer 200 through a continuous process. In an embodiment, for example, the anti-reflection layer 300 may include color filters which selectively transmit light of a specific color and a black matrix arranged between the color filters. Alternatively, the anti-reflection layer 300 may be omitted, and a polarizer may be arranged on the touch sensor layer 200.

The window member 400 may be attached to the anti-reflection layer 300 through the adhesive layer AD. The window member 400 may include a base film including a glass film or a synthetic resin film. The window member 400 may further include an anti-reflection layer or an anti-fingerprint layer.

In this specification, a plane may be defined as the first direction DR1 and the second direction DR2 intersecting the first direction DR1. In an embodiment, for example, the first direction DR1 and the second direction DR2 may be perpendicular to each other. In addition, the third direction DR3 may be perpendicular to the plane.

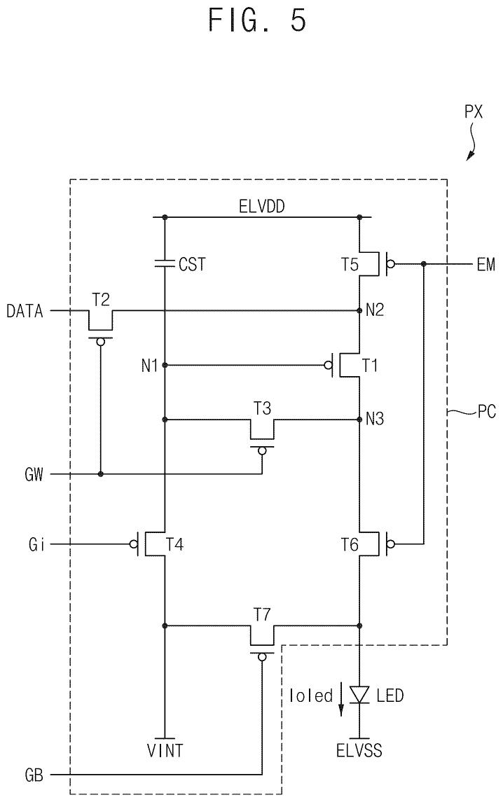

FIG. 5 is a circuit diagram illustrating a circuit structure of a pixel in FIG. 1.

Referring to FIG. 5, an embodiment of pixel PX may include a pixel driving circuit part PC and a light emitting element LED electrically connected to the pixel driving circuit part PC. The pixel driving circuit part PC may generate a driving current Ioled, and the light emitting element LED may generate light based on the driving current Ioled.

The pixel driving circuit part PC may include a first transistor T1, a second transistor T2, a third transistor T3, a fourth transistor T4, a fifth transistor T5, a sixth transistor T6, a seventh transistor T7, and a storage capacitor CST.

In an embodiment, the first transistor T1, the second transistor T2, the third transistor T3, the fourth transistor T4, the fifth transistor T5, the sixth transistor T6, and the seventh transistor T7 may be p-channel metal-oxide-semiconductor (PMOS) transistors. However, the embodiments of the present disclosure are not necessarily limited thereto, and at least one selected from the first transistor T1, the second transistor T2, the third transistor T3, the fourth transistor T4, the fifth transistor T5, the sixth transistor T6, and the seventh transistor T7 may be n-channel metal-oxide-semiconductor (NMOS) transistors, and the remaining thereof may be PMOS transistors.

In an embodiment where the pixel driving circuit part PC includes an NMOS transistor and a PMOS transistor, the active pattern of the NMOS transistor may include an oxide semiconductor, and the active pattern of the PMOS transistor may include a silicon semiconductor. However, embodiments of the present disclosure are not necessarily limited to this, and the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current Ioled to the light emitting element LED.

The second transistor T2 may include a gate electrode, a first electrode, and a second electrode. A first gate signal GW may be applied to the gate electrode of the second transistor T2. A data voltage DATA may be applied to the first electrode of the second transistor T2. The second electrode of the second transistor T2 may be connected to the second node N2.

The second transistor T2 may be turned on or off in response to the first gate signal GW. For example, when the first gate signal GW has an activation level, the second transistor T2 may be turned on. In this case, the second transistor T2 may provide the data voltage DATA to the second node N2. Conversely, when the first gate signal GW has an inactivation level, the second transistor T2 may be turned off. In this case, the second transistor T2 may block the supply of the data voltage DATA.

The third transistor T3 may include a gate electrode, a first electrode, and a second electrode. The first gate signal GW may be applied to the gate electrode of the third transistor T3. The first electrode of the third transistor T3 may be connected to the third node N3. The second electrode of the third transistor T3 may be connected between the first node N1 and a second electrode of the fourth transistor T4.

The fourth transistor T4 may include a gate electrode, a first electrode, and the second electrode. A second gate signal Gi may be applied to the gate electrode of the fourth transistor T4. An initialization voltage VINT may be applied to the first electrode of the fourth transistor T4. The second electrode of the fourth transistor T4 may be connected to the second electrode of the third transistor T3.

The fourth transistor T4 may be turned on or off in response to the second gate signal Gi. For example, when the second gate signal Gi has an activation level, the fourth transistor T4 may be turned on. In this case, the fourth transistor T4 may provide the initialization voltage VINT to the second electrode of the third transistor T3. Conversely, when the second gate signal Gi has an inactivation level, the fourth transistor T4 may block the supply of the initialization voltage VINT.

The fifth transistor T5 may include a gate electrode, a first electrode, and a second electrode. An emission control signal EM may be applied to the gate electrode of the fifth transistor T5. A driving voltage ELVDD may be applied to the first electrode of the fifth transistor T5. The second electrode of the fifth transistor T5 may be connected to the second node N2.

The sixth transistor T6 may include a gate electrode, a first electrode, and a second electrode. The emission control signal EM may be applied to the gate electrode of the sixth transistor T6. The first electrode of the sixth transistor T6 may be connected to the third node N3. The second electrode of the sixth transistor T6 may be connected to a second electrode of the seventh transistor T7.

The fifth transistor T5 and the sixth transistor T6 may be turned on or off in response to the emission control signal EM. For example, when the emission control signal EM has an activation level, the fifth transistor T5 and the sixth transistor T6 may be turned on. In this case, the fifth transistor T5 and the sixth transistor T6 may provide the driving current Ioled generated by the first transistor T1 to an anode electrode of the light emitting element LED. Conversely, when the emission control signal EM has an inactivation level, the fifth transistor T5 and the sixth transistor T6 may block the supply of the driving current Ioled generated by the first transistor T1.

The seventh transistor T7 may include a gate electrode, a first electrode, and the second electrode. A third gate signal GB may be applied to the gate electrode of the seventh transistor T7. The initialization voltage VINT may be applied to the first electrode of the seventh transistor T7. The second electrode of the seventh transistor T7 may be connected to the second electrode of the sixth transistor T6.

The seventh transistor T7 may be turned on or off in response to the third gate signal GB. For example, when the third gate signal GB has an activation level, the seventh transistor T7 may be turned on. In this case, the seventh transistor T7 may provide the initialization voltage VINT to the anode electrode of the light emitting element LED. Conversely, when the third gate signal GB has an inactivation level, the seventh transistor T7 may block the supply of the initialization voltage VINT.

In an embodiment, the first electrode of each of the first, second, third, fourth, fifth, sixth, and seventh transistors T1, T2, T3, T4, T5, T6, and T7 may be a source electrode, and the second electrode of each of the first, second, third, fourth, fifth, sixth, and seventh transistors T1, T2, T3, T4, T5, T6, and T7 may be a drain electrode. However, the embodiments of the present disclosure are not necessarily limited to this, and the first electrode of at least one of the first, second, third, fourth, fifth, sixth, and seventh transistors T1, T2, T3, T4, T5, T6, and T7 may be a drain electrode, and the first electrodes of the remaining of the first, second, third, fourth, fifth, sixth, and seventh transistors T1, T2, T3, T4, T5, T6, and T7 may be source electrodes.

The storage capacitor CST may include a first electrode and a second electrode. The driving voltage ELVDD may be applied to the first electrode of the storage capacitor CST. The second electrode of the storage capacitor CST may be connected to the first node N1.

The light emitting element LED may include the anode electrode and a cathode electrode. The anode electrode of the light emitting element LED may be connected to the second electrode of the sixth transistor T6 and the second electrode of the seventh transistor T7. The common voltage ELVSS may be applied to the cathode electrode of the light emitting element LED. The common voltage ELVSS may have a lower voltage level than the driving voltage ELVDD.

In an embodiment, as shown in FIG. 5, one pixel driving circuit PC may include seven transistors and one capacitor, but embodiments of the present disclosure are not necessarily limited thereto.

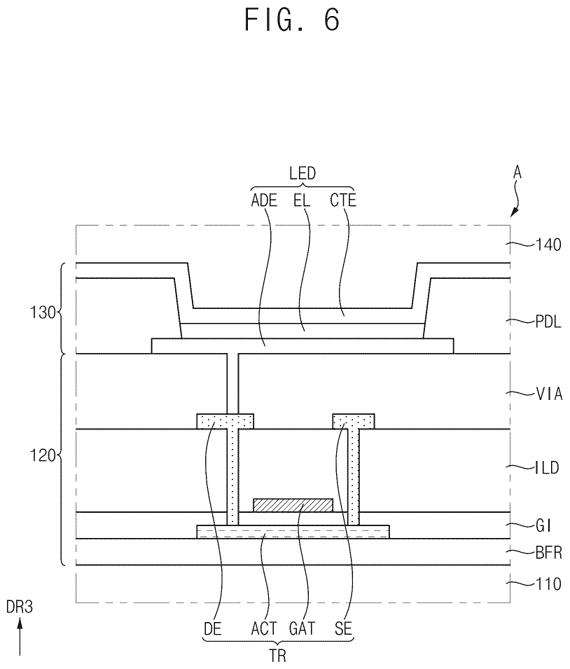

FIG. 6 is an enlarged cross-sectional view of area A of FIG. 2.

Referring to FIG. 6, as described above, an embodiment of the display panel DP may include the substrate 110, the pixel circuit layer 120, the light emitting element layer 130, and the encapsulation layer 140. The pixel circuit layer 120 may include a buffer layer BFR, a gate insulating layer GI, a transistor TR, an interlayer insulating layer ILD, and a via insulating layer VIA. In addition, the light emitting element layer 130 may include a pixel defining layer PDL and a light emitting element LED. Here, the transistor TR may include an active pattern ACT, a gate electrode GAT, a source electrode SE, and a drain electrode DE, and the light emitting element LED may include an anode electrode ADE, a light emitting layer EL, and a cathode electrode CTE.

The buffer layer BFR may be arranged on the substrate 110. The buffer layer BFR may effectively prevent metal atoms or impurities from diffusing from the substrate 110 to the transistor TR. In addition, the buffer layer BFR may improve the flatness of the surface of the substrate 110 when the surface of the substrate 110 is not uniform. In an embodiment, for example, the buffer layer BFR may include an inorganic material such as silicon oxide (SiOₓ), silicon nitride (SiNₓ), silicon oxynitride (SiOₓN_{y}), or the like. These can be used alone or in combination with each other.

The active pattern ACT may be arranged on the buffer layer BFR. The active pattern ACT may include a metal oxide semiconductor, an inorganic semiconductor (e.g., amorphous silicon, poly silicon, etc.), or an organic semiconductor. The active pattern ACT may include a source region, a drain region, and a channel region located between the source region and the drain region.

The metal oxide semiconductor may include binary compounds (ABₓ), ternary compounds (ABₓC_{y}), quaternary compounds (ABₓC_{y}D_{z}), or the like containing indium (In), zinc (Zn), gallium (Ga), tin (Sn), titanium (Ti), aluminum (Al), hafnium (Hf), zirconium (Zr), magnesium (Mg), or the like. For example, the metal oxide semiconductor may include zinc oxide (ZnOₓ) (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), or the like. These can be used alone or in combination with each other.

The gate insulating layer GI may be arranged on the buffer layer BFR. The gate insulating layer GI may sufficiently cover the active pattern ACT and may have a substantially flat top surface without creating a step around the active pattern ACT. Alternatively, the gate insulating layer GI may cover the active pattern ACT and may be arranged along the profile of the active pattern ACT with a uniform thickness. In an embodiment, for example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These can be used alone or in combination with each other.

The gate electrode GAT may be arranged on the gate insulating layer GI. The gate electrode GAT may overlap the channel area of the active pattern ACT in the third direction DR3. The gate electrode GAT may include metal, alloy, metal nitride, conductive metal oxide, transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. In addition, examples of the metal nitride may include aluminum nitride (AlNₓ), tungsten nitride (WNₓ), chromium nitride (CrNₓ), or the like. These can be used alone or in combination with each other.

The interlayer insulating layer ILD may be arranged on the gate insulating layer GI. The interlayer insulating layer ILD may sufficiently cover the gate electrode GAT and may have a substantially flat upper surface without creating a step around the gate electrode GAT. Alternatively, the interlayer insulating layer ILD may cover the gate electrode GAT and may be arranged along the profile of the gate electrode GAT with a uniform thickness. In an embodiment, for example, the interlayer insulating layer ILD may include an inorganic material such as silicon oxide, silicon nitride, silicon carbide, silicon oxynitride, silicon oxycarbide, or the like. These can be used alone or in combination with each other.

The source electrode SE and the drain electrode DE may be arranged on the interlayer insulating layer ILD. The source electrode SE may be connected to the source region of the active pattern ACT through a contact hole penetrating a first portion of the gate insulating layer GI and the interlayer insulating layer ILD, and the drain electrode DE may be connected to the drain region of the active pattern ACT through a contact hole penetrating a second portion of the gate insulating layer GI and the interlayer insulating layer ILD. In an embodiment, for example, each of the source electrode SE and the drain electrode DE may include a metal, alloy, metal nitride, conductive metal oxide, transparent conductive material, or the like. These can be used alone or in combination with each other.

Accordingly, the transistor TR including the active pattern ACT, the gate electrode GAT, the source electrode SE, and the drain electrode DE may be arranged in the display area (e.g., the display area DA of FIGS. 1 and 2) on the substrate 110.

The via insulating layer VIA may be arranged on the interlayer insulating layer ILD. The via insulating layer VIA may sufficiently cover the source electrode SE and the drain electrode DE. The via insulating layer VIA may include an inorganic material or an organic material. In an embodiment, the via insulating layer VIA may include an organic material. In an embodiment, for example, the via insulating layer VIA may include organic materials such as phenolic resin, polyacrylates resin, polyimides resin, polyamides resin, siloxane resin, epoxy resin, or the like. These can be used alone or in combination with each other.

The anode electrode ADE may be arranged on the via insulating layer VIA. The anode electrode ADE may be connected to the drain electrode DE (or the source electrode SE) through a contact hole penetrating the via insulating layer VIA. In an embodiment, for example, the anode electrode ADE may include metal, alloy, metal nitride, conductive metal oxide, transparent conductive material, or the like. These can be used alone or in combination with each other. In an embodiment, the anode electrode ADE may have a layered structure including ITO/Ag/ITO. However, embodiments of the present disclosure are not necessarily limited thereto.

The pixel defining layer PDL may be arranged on the via insulating layer VIA. The pixel defining layer PDL may cover an edge of the anode electrode ADE. In addition, an opening exposing at least a portion of an upper surface of the anode electrode ADE may be defined in the pixel defining layer PDL. In an embodiment, for example, the pixel defining layer PDL may include an inorganic material or an organic material. In an embodiment, the pixel defining layer PDL may include an organic material such as epoxy resin, siloxane resin, or the like. These can be used alone or in combination with each other. In another embodiment, the pixel defining layer PDL may include an inorganic material and/or an organic material containing a light blocking material such as black pigment, black dye, or the like.

The light emitting layer EL may be arranged on the anode electrode ADE. In an embodiment, for example, the light emitting layer EL may be arranged in the opening of the pixel defining layer PDL. The light emitting layer EL may include a light emitting material which emits light of a preset color. In an embodiment, for example, the light emitting layer EL may include a light emitting material which emits red light, green light, or blue light.

The cathode electrode CTE may be arranged on the pixel defining layer PDL and the light emitting layer EL. In an embodiment, for example, the cathode electrode CTE may include metal, alloy, metal nitride, conductive metal oxide, transparent conductive material, or the like. These can be used alone or in combination with each other.

Accordingly, the light emitting element LED including the anode electrode ADE, the light emitting layer EL, and the cathode electrode CTE may be arranged in the display area DA on the substrate 110. The light emitting element LED may be electrically connected to the transistor TR. Accordingly, the light emitting element LED may receive a driving signal from the transistor TR and generate light based on the driving signal.

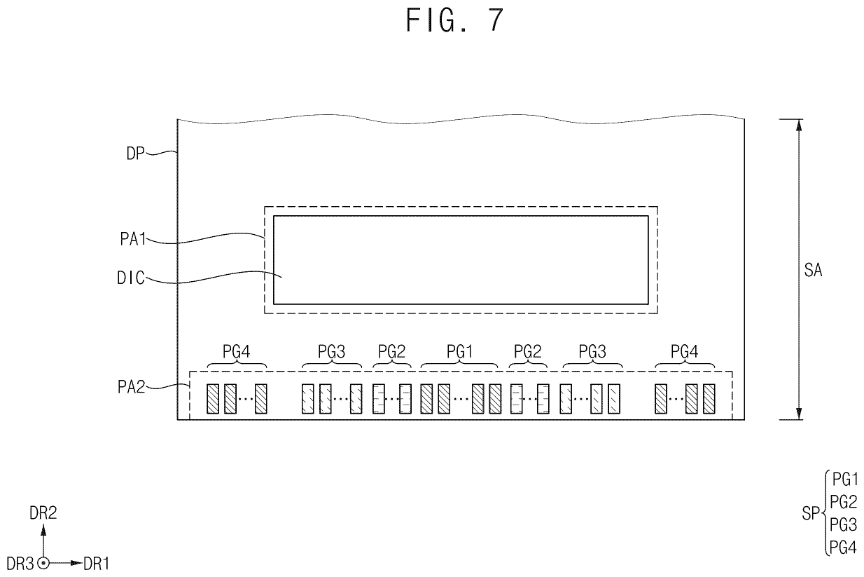

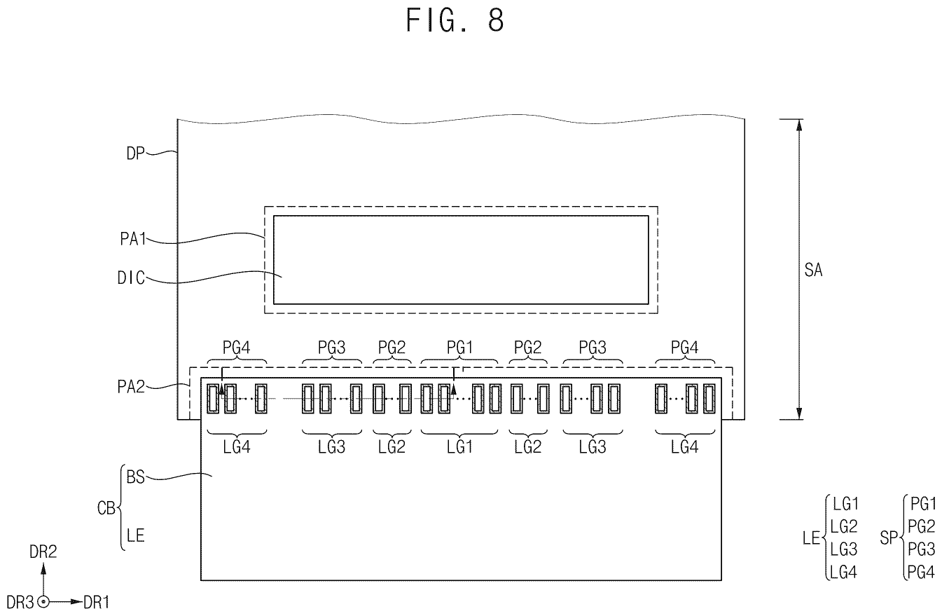

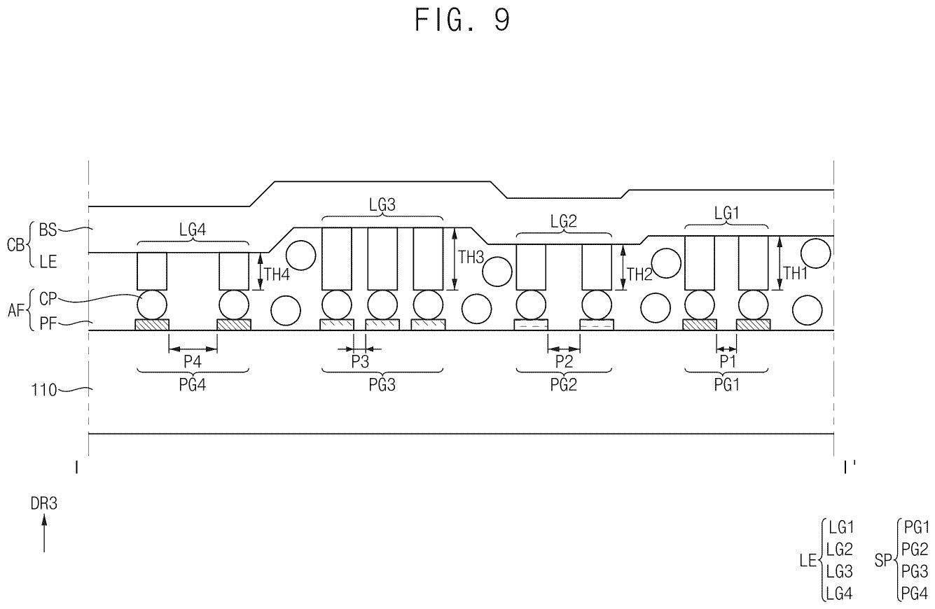

FIG. 7 is an enlarged plan view of a display panel and a driving integrated circuit bonded to the display panel arranged in a sub-area of FIG. 1. FIG. 8 is a plan view illustrating the display panel the driving integrated circuit of FIG. 7 and a circuit board bonded to the display panel. FIG. 9 is a cross-sectional view illustrating an example of a cross-section taken along line I-I′ of FIG. 8.

Referring to FIGS. 7, 8, and 8, in an embodiment, the driving integrated circuit DIC may be bonded to the first pad area PA1 on the display panel DP. That is, the driving integrated circuit DIC may be connected to the first pad area PA1. In an embodiment, a plurality of pads may be arranged in the first pad area PA1, and the driving integrated circuit DIC may include a plurality of bump electrodes. As the bump electrodes are connected one-to-one with the pads (i.e., connected to the pads in a one-to-one correspondence with the pads), the driving integrated circuit DIC may be bonded to the first pad area PA1.

The display panel DP further include a plurality of signal pads SP which may be arranged in the second pad area PA2 on the substrate 110 and spaced apart from each other along the first direction DR1. The signal pads SP may provide various signals and voltages to the driving integrated circuit DIC and the drivers. In an embodiment, for example, the signal pads SP may include metal, alloy, metal nitride, conductive metal oxide, transparent conductive material, or the like. These can be used alone or in combination with each other.

The signal pads SP may be grouped or combined into a plurality of pad groups. In an embodiment, for example, the pad groups may include a first pad group PG1, a second pad group PG2, a third pad group PG3, and a fourth pad group PG4. The first pad group PG1 may include first signal pads, the second pad group PG2 may include second signal pads, the third pad group PG3 may include third signal pads, and the fourth pad group PG4 may include fourth signal pads.

In an embodiment, the first pad group PG1 may be located at the center portion of the second pad area PA2, the second pad group PG2 may be located between the first pad group PG1 and the third pad group PG3, the third pad group PG3 may be located between the fourth pad group PG4 and the second pad group PG2, and the fourth pad group PG4 may be located at the edge portion of the second pad area PA2. In addition, the second pad group PG2, the third pad group PG3, and the fourth pad group PG4 may be symmetrically arranged on the left and right sides of the first pad group PG1, respectively, in the plan view.

In an embodiment, a signal applied to the first pad group PG1, a signal applied to the second pad group PG2, a signal applied to the third pad group PG3, and a signal applied to the fourth pad group PG4 may be different from each other.

In an embodiment, for example, a data voltage, a power voltage, and an initialization voltage may be applied to the first pad group PG1, the second pad group PG2, and the third pad group PG3, respectively, and a control signal for controlling the gate driver and the emission driver may be applied to the fourth pad group PG4. In such an embodiment, the first pad group PG1, the second pad group PG2, and the third pad group PG3 may be electrically connected to the driving integrated circuit DIC through lines, and the fourth pad group PG4 may be electrically connected to the gate driver and the emission driver through lines. However, embodiments of the present disclosure are not necessarily limited thereto.

In an embodiment, a pitch between the signal pads SP included in one of the pad groups may be different from a pitch between the signal pads SP included in another pad group of the pad groups. Accordingly, it is possible to secure sufficient space for arranging electronic modules including various functional modules for driving the display device DD.

In an embodiment, for example, the first signal pads may be spaced apart from each other at a first pitch P1, the second signal pads may be spaced apart from each other at a second pitch P2, the third signal pads may be spaced apart from each other at a third pitch P3, and the fourth signal pads may be spaced apart from each other at a fourth pitch P4, as shown in FIG. 9. The first pitch P1, the second pitch P2, the third pitch P3, and the fourth pitch P4 may be different from each other.

In an embodiment, for example, the fourth pitch P4 may be greater than the second pitch P2, the second pitch P2 may be greater than the first pitch P1, and the first pitch P1 may be greater than the third pitch P3. That is, among the first pitch P1, the second pitch P2, the third pitch P3, and the fourth pitch P4, the fourth pitch P4 may be the greatest and the third pitch P3 may be the smallest. However, embodiments of the present disclosure are not necessarily limited thereto.

The circuit board CB may include a base film BS and a plurality of lead electrodes LE arranged on the base film BS and spaced apart from each other. The lead electrodes LE may be connected one-to-one with the signal pads SP. Accordingly, one end of the circuit board CB may be bonded to the second pad area PA2.

In an embodiment, the lead electrodes LE may be grouped into a plurality of lead groups having different thicknesses. In an embodiment, for example, the lead groups may include a first lead group LG1, a second lead group LG), a third lead group LG3, and a fourth lead group LG4. The first lead group LG1 may include first lead electrodes, the second lead group LG2 may include second lead electrodes, the third lead group LG3 may include third lead electrodes, and the fourth lead group LG4 may include fourth lead electrodes.

The first lead group LG1 may be connected to the first pad group PG1, the second lead group LG2 may be connected to the second pad group PG2, the third lead group LG3 may be connected to the third pad group PG3, and the fourth lead group LG4 may be connected to the fourth pad group PG4. That is, the first lead electrodes may be connected one-to-one with the first signal pads, the second lead electrodes may be connected one-to-one with the second signal pads, the third lead electrodes may be connected one-to-one with the third signal pads, and the fourth lead electrodes may be connected one-to-one with the fourth signal pads.

As the signal applied to the first pad group PG1, the signal applied to the second pad group PG2, the signal applied to the third pad group PG3, and the signal applied to the fourth pad group PG4 are different from each other, the signal applied to the first lead group LG1, the signal applied to the second lead group LG2, the signal applied to the third lead group LG3, and the signal applied to the fourth lead group LG4 may be different from each other.

In an embodiment, for example, each of the first lead electrodes may have a first thickness TH1, each of the second lead electrodes may have a second thickness TH2, each of the third lead electrodes may have a third thickness TH3, and each of the fourth lead electrodes may have a fourth thickness TH4. The first thickness TH1, the second thickness TH2, the third thickness TH3, and the fourth thickness TH4 may be different from each other.

In an embodiment, for example, the third thickness TH3 may be thicker than the second thickness TH2, the first thickness TH1 may be thicker than the second thickness TH2, and the second thickness TH2 may be thicker than the fourth thickness TH4. That is, among the first thickness TH1, the second thickness TH2, the third thickness TH3, and the fourth thickness TH4, the third thickness TH3 may be the thickest and the fourth thickness TH4 may be the thinnest. However, embodiments of the present disclosure are not necessarily limited thereto.

Each of the lead electrodes LE may have a multilayer structure. In an embodiment, each of the lead electrodes LE may include a first conductive layer arranged on the base film BS and including a metal, a second conductive layer arranged on the first conductive layer and including a metal, and a cover layer covering the first and second conductive layers. A detailed description of the structure of the lead electrodes LE will be provided later.

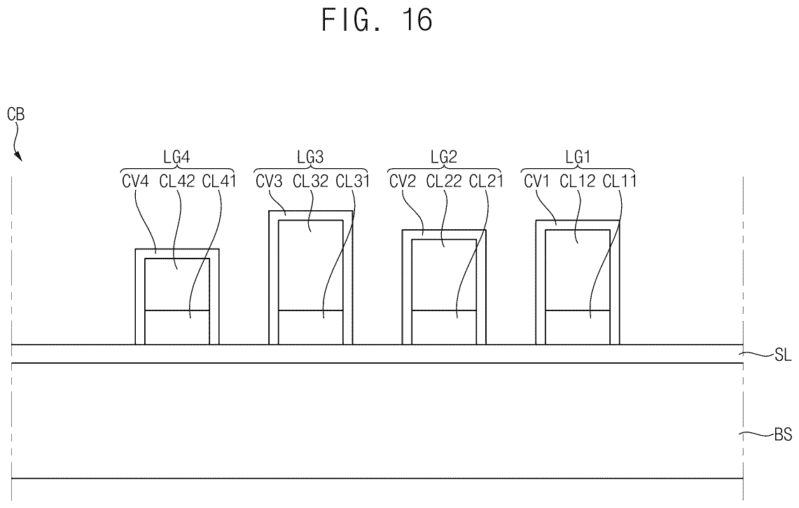

In an embodiment, the circuit board CB may further include a seed layer (e.g., a seed layer SL in FIG. 16) arranged to continuously extend between the base film BS and the lead electrodes LE and including a metal.

In an embodiment, as described above, the circuit board CB may be bonded to the second pad area PA2 on the display panel DP. In such an embodiment, the circuit board CB may be connected to the second pad area PA2. In such an embodiment, as the lead electrodes may be connected one-to-one with the signal pads, the circuit board CB may be bonded to the second pad area PA2.

In an embodiment, the circuit board CB may be bonded to the second pad area PA2 on the display panel DP through an anisotropic conductive film AF. Accordingly, the circuit board CB may be electrically connected to the display panel DP through the anisotropic conductive film AF.

The anisotropic conductive film AF may include an adhesive film PF and a plurality of conductive particles CP arranged to be spaced apart from each other in the adhesive film PF.

The adhesive film PF may include an insulating polymer. In an embodiment, for example, the insulating polymer may include epoxy resin, acrylic resin, phenol resin, melamine resin, diallyl phthalate resin, urea resin, polyimide resin, polystyrene resin, polyurethane resin, polyethylene resin, polyvinyl acetate resin, or the like. These can be used alone or in combination with each other.

Some of the conductive particles CP may be arranged between the signal pads SP and the lead electrodes LE, and others may not be arranged between the signal pads SP and the lead electrodes LE. Accordingly, the signal pads SP and the lead electrodes LE may be electrically connected through the conductive particles CP, and accordingly, the display panel DP and the circuit board CB may be electrically connected.

In an embodiment, for example, each of the conductive particles CP may have a structure including a core including a polymer and a conductive layer surrounding the core.

In an embodiment, as described above, the pitch between the signal pads SP included in one of the pad groups may be different from the pitch between the signal pads SP included in another pad group of the pad groups. In this case, when using the anisotropic conductive film AF of a relatively thin thickness, the amount of the adhesive film PF may be insufficient in the pad group where the signal pads SP are spaced apart from each other with a large pitch, resulting in voids. In this case, when using the anisotropic conductive film AF with a relatively thick thickness, the amount of the adhesive film PF may be excessive in the pad group where the signal pads SP are spaced apart from each other with a small pitch, resulting in a large bonding gap between the signal pads SP and the lead electrodes LE.

In the display device DD according to embodiments of the present disclosure, the lead electrodes LE of the circuit board CB may be grouped into the plurality of lead groups having different thicknesses. In such embodiments, the thickness of each of the lead electrodes LE included in one lead group of the lead groups to which a first signal is applied may be different from the thickness of each of the lead electrodes LE included in another lead group of the lead groups to which a second signal different from the first signal is applied. Accordingly, voids may not occur in the anisotropic conductive film AF, and an overall uniform bonding gap may be realized between the signal pads SP and the lead electrodes LE.

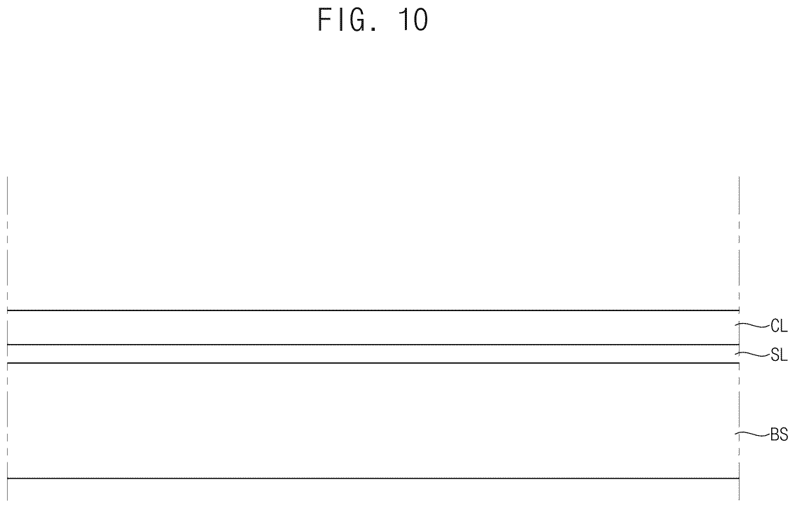

FIGS. 10, 11, 12, 13, 14, 15, and 16 are cross-sectional views for explaining a method of the manufacturing the circuit board of FIGS. 8 and 9. For convenience of illustration and description, FIG. 16 shows only one lead electrode for each of the first lead group LG1, the second lead group LG2, the third lead group LG3, and the fourth lead group LG4.

Referring to FIG. 10, in an embodiment of a method of the manufacturing the circuit board, the base film BS may be formed or prepared. The base film BS may be a flexible substrate including a flexible material. In an embodiment, for example, the base film BS may include polyethylene terephthalate (PET), polyimide (PI), polycarbonate (PC), polyethylene (PE), polypropylene (PP), polysulfone (PSF), polymethyl methacrylate (PMMA), or the like. These can be used alone or in combination with each other.

The seed layer SL may be formed on the base film BS. The seed layer SL may be formed to continuously extend on the base film BS. That is, the seed layer SL may be formed on an entire surface of the base film BS. In an embodiment, for example, the seed layer SL may include metals such as silver (Ag), titanium (Ti), chromium (Cr), nickel (Ni), aluminum (Al), platinum (Pt), gold (Au), tungsten (W), copper (Cu), molybdenum (Mo), or the like. These can be used alone or in combination with each other. In an embodiment, the seed layer SL may include copper (Cu). However, embodiments of the present disclosure are not necessarily limited thereto.

A conductive layer CL may be formed on the seed layer SL. The conductive layer CL may be formed to continuously extend on the seed layer SL. That is, the conductive layer CL may be formed on an entire surface of the seed layer SL. In an embodiment, for example, the conductive layer CL may include metals such as silver (Ag), titanium (Ti), chromium (Cr), nickel (Ni), aluminum (Al), platinum (Pt), gold (Au), tungsten (W), copper (Cu), molybdenum (Mo), or the like. These can be used alone or in combination with each other. In an embodiment, the conductive layer CL may include copper (Cu). However, embodiments of the present disclosure are not necessarily limited thereto.

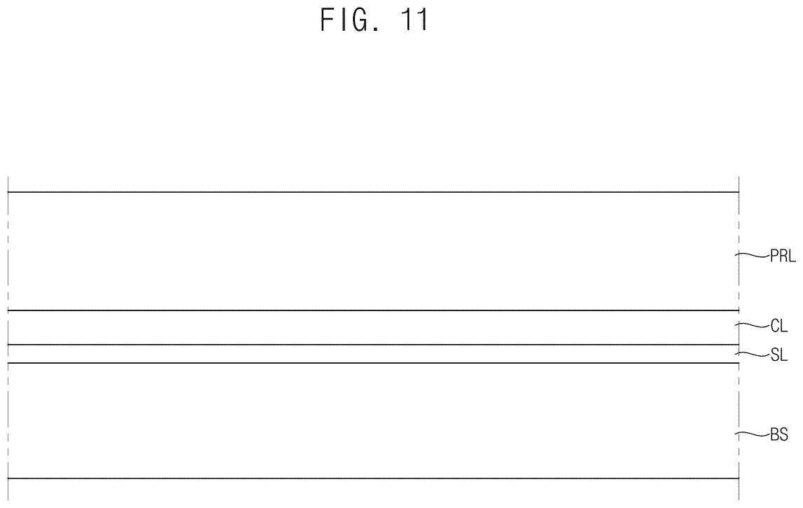

Referring to FIG. 11, a photoresist layer PRL may be formed on the conductive layer CL. In an embodiment, for example, the photoresist layer PRL may be a dry film. The photoresist layer PRL may include positive photoresist or negative photoresist.

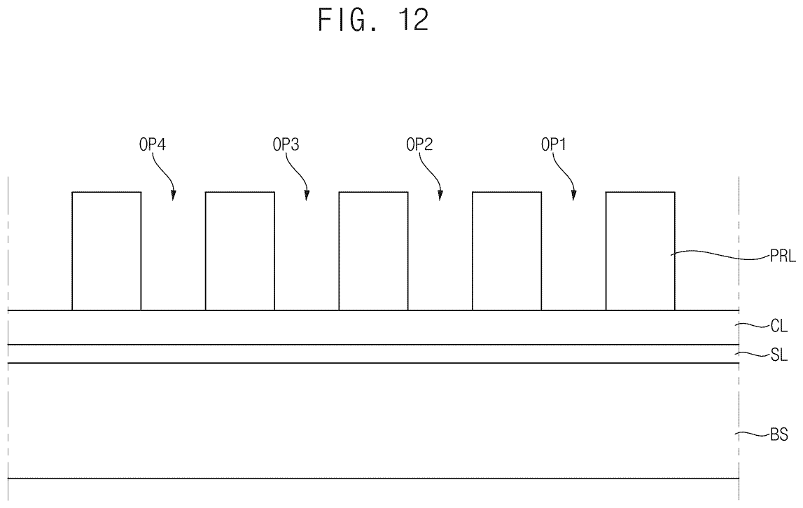

Referring to FIG. 12, in an embodiment of a method of the manufacturing the circuit board, a plurality of openings spaced apart from each other may be formed in the photoresist layer PRL by exposing and developing the photoresist layer PRL. The openings may expose at least a portion of the conductive layer CL. In an embodiment, for example, the openings may include a first opening OP1, a second opening OP2, a third opening OP3, and a fourth opening OP4 spaced apart from each other.

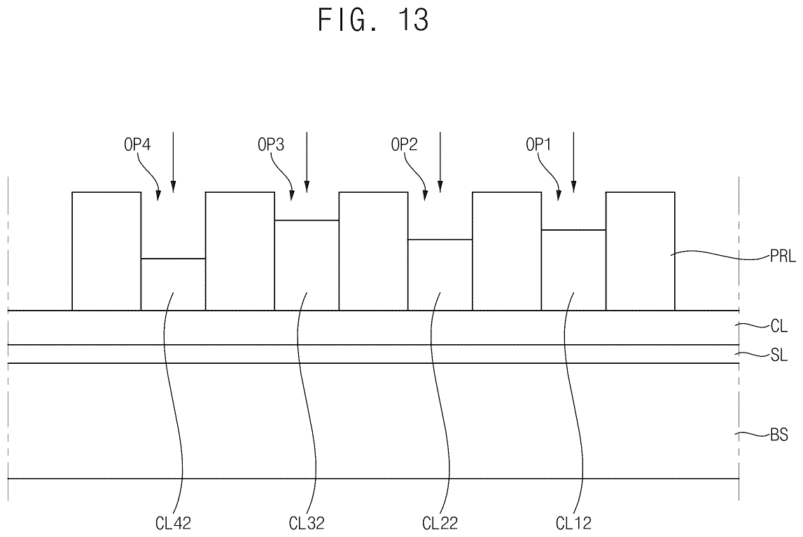

Referring to FIG. 13, in an embodiment of a method of the manufacturing the circuit board, the openings may be filled with metal in different amounts. in an embodiment, the metal may be plated in different amounts in the openings. In an embodiment, for example, while metal is plated in one of the openings, the remaining openings may be masked.

In an embodiment, for example, a metal may be plated in the first opening OP1 to form a first-second conductive layer CL12, a metal may be plated in the second opening OP2 to form a second-second conductive layer CL22, a metal may be plated in the third opening OP3 to form a third-second conductive layer CL32, and a metal may be plated in the fourth opening OP4 to form a fourth-second conductive layer CL42. The first-second conductive layer CL12, the second-second conductive layer CL22, the third-second conductive layer CL32, and the fourth-second conductive layer CL42 may be formed to have different thicknesses from each other.

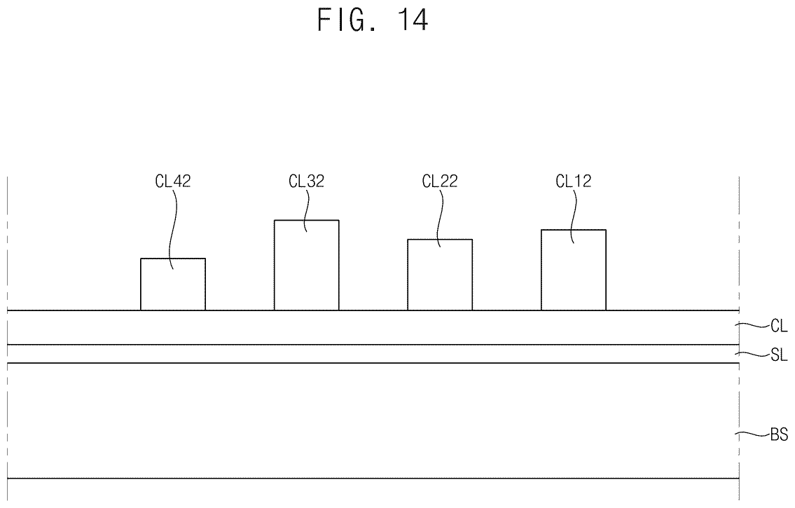

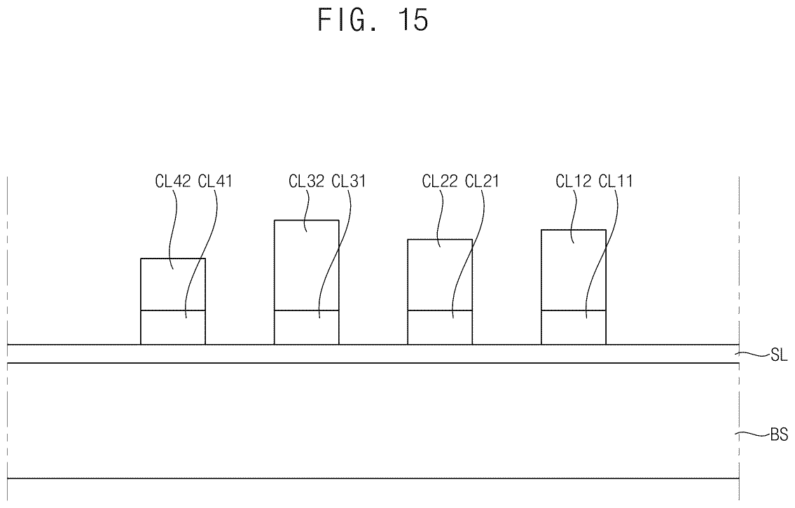

Referring to FIGS. 14 and 15, in an embodiment of a method of the manufacturing the circuit board, the photoresist layer PRL may be removed.

Portions of the conductive layer CL that do not overlap (or are not covered by) the first-second conductive layer CL12, the second-second conductive layer CL22, the third-second conductive layer CL32, and the fourth-second conductive layer CL42 may be removed through an etching process. Accordingly, a first-first conductive layer CL11 contacting the first-second conductive layer CL12, a second-first conductive layer CL21 contacting the second-second conductive layer CL22, a third-first conductive layer CL31 contacting the third-second conductive layer CL32, and a fourth-first conductive layer CL41 contacting the fourth-second conductive layer CL42 may be formed.

Referring to FIG. 16, in an embodiment of a method of the manufacturing the circuit board, a first cover layer CV1 covering the first-first conductive layer CL11 and the first-second conductive layer CL12, a second cover layer CV2 covering the second-first conductive layer CL21 and the second-second conductive layer CL22, a third cover layer CV3 covering the third-first conductive layer CL31 and the third-second conductive layer CL32, and a fourth cover layer CV4 covering the fourth-first conductive layer CL41 and the fourth-second conductive layer CL42 may be formed. The first, second, third, and fourth cover layers CV1, CV2, CV3, and CV4 may be formed through plating. In an embodiment, the first, second, third, and fourth cover layers CV1, CV2, CV3, and CV4 may include gold (Au). However, embodiments of the present disclosure are not necessarily limited thereto.

As the first, second, third, and fourth cover layers CV1, CV2, CV3, and CV4 are formed, the first lead group LG1 including the first lead electrode including the first-first conductive layer CL11, the first-second conductive layer CL12, and the first cover layer CV1, the second lead group LG2 including the second lead electrode including the second-first conductive layer CL21, the second-second conductive layer CL22, and the second cover layer CV2, the third lead group LG3 including the third lead electrode including the third-first conductive layer CL31, the third-second conductive layer CL32, and the third cover layer CV3, and the fourth lead group LG4 including the fourth lead electrode including the fourth-first conductive layer CL41, the fourth-second conductive layer CL42, and the fourth cover layer CV4 may be formed.

As a result, the metal may be plated in different amounts in the first, second, third, and fourth openings OP1, OP2, OP3, and OP4 through masking, and thus the first, second, third, and fourth lead electrodes having different thicknesses may be formed.

Accordingly, the circuit board CB shown in FIGS. 8 and 9 may be manufactured.

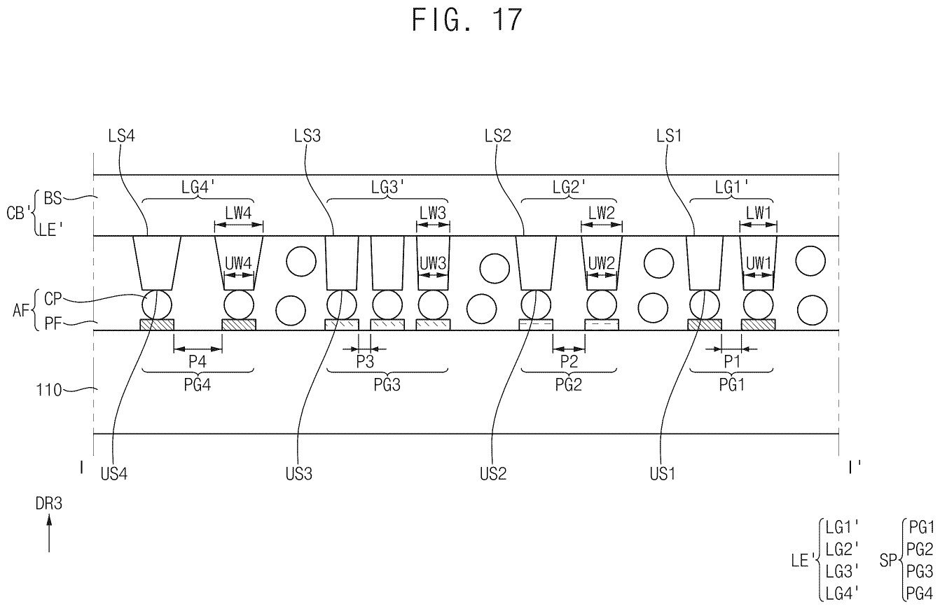

FIG. 17 is a cross-sectional view illustrating another example of a cross-section taken along line I-I′ of FIG. 8.

An embodiment of a circuit board CB′ shown in FIG. 17 may be substantially the same as or similar to the embodiments of the circuit board CB described above with reference to FIGS. 8 and 9 except for lead electrodes LE′. Therefore, any repetitive detailed descriptions of the same or like elements as those described above will be omitted or simplified.

Referring to FIG. 17, in an embodiment, the signal pads SP may be grouped into a plurality of pad groups. In an embodiment, the pitch between the signal pads SP included in one of the pad groups may be different from the pitch between the signal pads SP included in another pad group of the pad groups.

The circuit board CB′ may include a base film BS and a plurality of lead electrodes LE′ arranged on the base film BS and spaced apart from each other. The lead electrodes LE′ may be connected one-to-one with the signal pads SP. Accordingly, one end of the circuit board CB′ may be bonded to the second pad area PA2.

In an embodiment, the lead electrodes LE′ may be grouped into a plurality of lead groups with different ratios of a width of a lower surface to a width of an upper surface. That is, the ratio of the width of the lower surface to the width of the upper surface of each of the lead electrodes LE′ included in one lead group of the lead groups may be different from the ratio of the width of the upper surface to the width of the lower surface of each of the lead electrodes LE′ included in another lead group of the lead groups.

In an embodiment, the width of the upper surface of each of the lead electrodes LE′ may be different from the width of the lower surface of each of the lead electrodes LE′. In an embodiment, for example, each of the lead electrodes LE′ may have a trapezoidal shape with inclined sides in a cross-section. However, embodiments of the present disclosure are not necessarily limited thereto.

In an embodiment, for example, the lead groups may include a first lead group (G1′, a second lead group LG2′, a third lead group LG3′, and a fourth lead group LG4′. The first lead group LG1′ may include first lead electrodes, the second lead group LG2′ may include second lead electrodes, the third lead group LG3′ may include third lead electrodes, and the fourth lead group LG4′ may include fourth lead electrodes.

The first lead group LG1′ may be connected to the first pad group PG1, the second lead group LG2′ may be connected to the second pad group PG2, the third lead group LG3′ may be connected to the third pad group PG3, and the fourth lead group LG4′ may be connected to the fourth pad group PG4.

In an embodiment, for example, a width LW1 of a first lower surface LS1 to a width UW1 of a first upper surface US1 of each of the first lead electrodes may have a first ratio (i.e., a ratio of the width LW1 of the first lower surface LS1 to the width UW1 of the first upper surface US1 of each of the first lead electrodes may be the first ratio), a width LW2 of a second lower surface LS2 to a width UW2 of a second upper surface US2 of each of the second lead electrodes may have a second ratio, a width LW3 of a third lower surface LS3 to a width UW3 of a third upper surface US3 of each of the third lead electrodes may have a third ratio, and a width LW4 of a fourth lower surface LS4 to a width UW4 of a fourth upper surface US4 of each of the fourth lead electrodes may have a fourth ratio. The first ratio, the second ratio, the third ratio, and the fourth ratio may be different from each other.

Here, the first, second, third, and fourth lower surfaces LS1, LS2, LS3, and LS4 may directly contact the base film BS, and the first, second, third, and fourth upper surfaces US1, US2, US3, and US4 may directly contact the conductive particles CP of the anisotropic conductive film AF.

In an embodiment, for example, the fourth ratio may be greater than the second ratio, the second ratio may be greater than the first ratio, and the first ratio may be greater than the third ratio. That is, among the first ratio, the second ratio, the third ratio, and the fourth ratio, the fourth ratio may be the greatest and the third ratio may be the smallest. However, embodiments of the present disclosure are not necessarily limited thereto.

Each of the lead electrodes LE′ may have a multilayer structure. In an embodiment, each of the lead electrodes LE′ may include a seed pattern arranged on the base film BS and including a metal, a conductive layer arranged on the seed pattern and including a metal, and a cover layer covering the seed pattern and the conductive layer and including gold (Au).

The circuit board CB′ may be bonded to the second pad area PA2 on the display panel DP through the anisotropic conductive film AF. Accordingly, the circuit board CB′ may be electrically connected to the display panel DP through the anisotropic conductive film AF.

The anisotropic conductive film AF may include the adhesive film PF and the conductive particles CP arranged to be spaced apart from each other in the adhesive film PF.

In the display device DD according to embodiments of the present disclosure, the lead electrodes LE′ of the circuit board CB′ may be grouped into the plurality of lead groups having different ratios of the width of the lower surface to the width of the upper surface. In such embodiments, the ratio of the width of the lower surface to the width of the upper surface of each of the lead electrodes LE′ included in one of the lead groups to which the first signal is applied may be different from the ratio of the width of the lower surface to the width of the upper surface of each of the lead electrodes LE′ included in another lead group of the lead groups to which a second signal different from the first signal is applied. Accordingly, voids may not occur in the anisotropic conductive film AF, and an overall uniform bonding gap may be realized between the signal pads SP and the lead electrodes LE′.

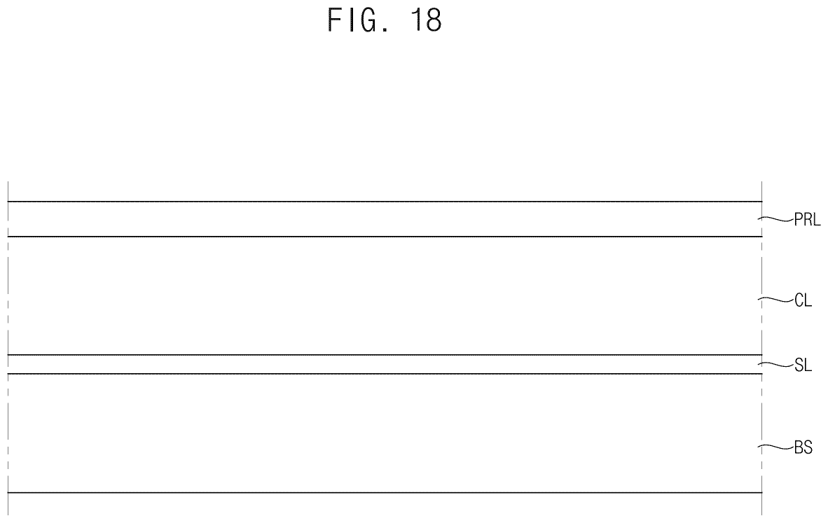

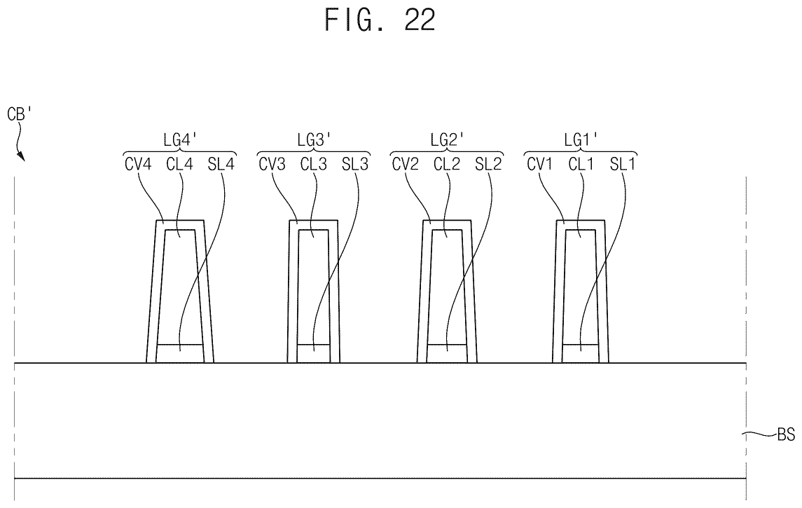

FIGS. 18, 19, 20, 21, and 22 are cross-sectional views for explaining a method of the manufacturing the circuit board of FIGS. 8 and 9. For convenience of illustration and description, FIG. 22 shows only one lead electrode for each of the first lead group LG1′, the second lead group LG2′, the third lead group LG3′, and the fourth lead group LG4′. Hereinafter, any repetitive detailed descriptions of the same or like elements as those of the embodiment of a method of manufacturing the circuit board CB described above with reference to FIGS. 10, 12, 13, 14, 15, and 16 will be omitted or simplified.

Referring to FIG. 18, in an embodiment of a method of the manufacturing the circuit board, the base film BS may be formed or prepared. The base film BS may be a flexible substrate including a flexible material.

A seed layer SL may be formed on the base film BS. The seed layer SL may be formed on the entire surface of the base film BS. In an embodiment, for example, the seed layer SL may include metals such as silver (Ag), titanium (Ti), chromium (Cr), nickel (Ni), aluminum (Al), platinum (Pt), gold (Au), tungsten (W), copper (Cu), molybdenum (Mo), or the like. These can be used alone or in combination with each other. In an embodiment, the seed layer SL may include copper (Cu). However, embodiments of the present disclosure are not necessarily limited thereto.

A conductive layer CL may be formed on the seed layer SL. The conductive layer CL may be formed on the entire surface of the seed layer SL. In an embodiment, for example, the conductive layer CL may include metals such as silver (Ag), titanium (Ti), chromium (Cr), nickel (Ni), aluminum (Al), platinum (Pt), gold (Au), tungsten (W), copper (Cu), molybdenum (Mo), or the like. These can be used alone or in combination with each other. In an embodiment, for example, the conductive layer CL may include copper (Cu). However, embodiments of the present disclosure are not necessarily limited thereto.

A photoresist layer PRL may be formed on the conductive layer CL. In an embodiment, for example, the photoresist layer PRL may be a dry film.

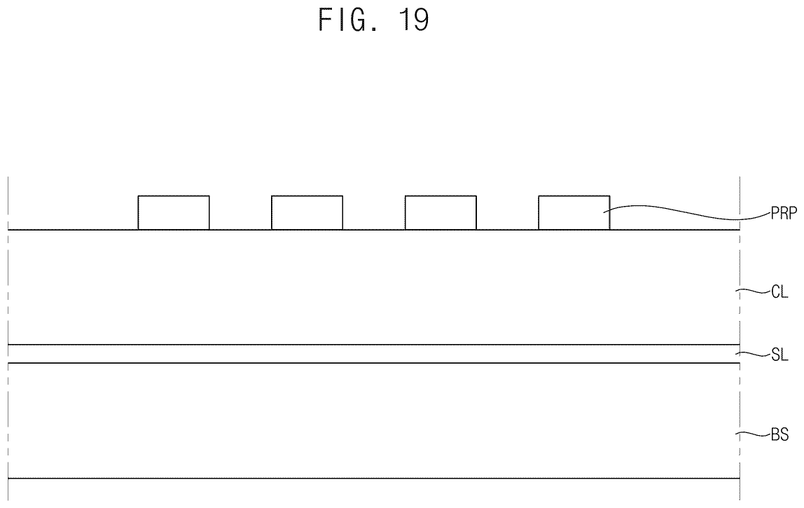

Referring further to FIG. 19, in an embodiment of a method of the manufacturing the circuit board, a plurality of photoresist patterns PRP spaced apart from each other may be formed by exposing and developing the photoresist layer PRL.

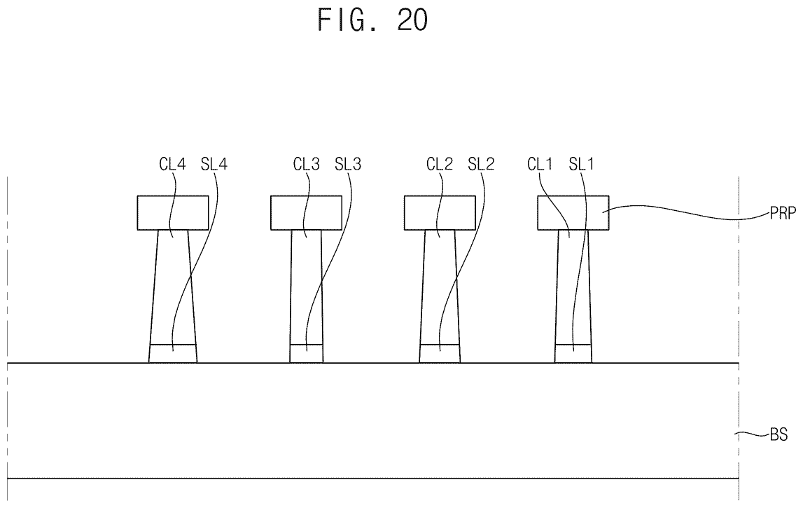

Referring further to FIG. 20, in an embodiment of a method of the manufacturing the circuit board, portions of the conductive layer CL and the seed layer SL that do not overlap the photoresist patterns PRP may be removed through an etching process. In an embodiment, for example, the etching process may be a wet etching process. Accordingly, a first seed pattern SL1 and a first conductive layer CL1 on the first seed pattern SL1 may be formed, a second seed pattern SL2 and a second conductive layer CL2 on the second seed pattern SL2 may be formed, a third seed pattern SL3 and a third conductive layer CL3 on the third seed pattern SL3 may be formed, and a fourth seed pattern SL4 and a fourth conductive layer CL4 on the fourth seed pattern SL4 may be formed.

That is, the first, second, third, and fourth seed patterns SL1, SL2, SL3, and SL4 may be formed by removing a portion of the seed layer SL, and the first, second, third, and fourth conductive layers CL1, CL2, CL3, and CL4 may be formed by removing a portion of the conductive layer cl.

By controlling the etchant in the etching process, preliminary lead electrodes having different ratios of the width of the lower surface and the width of the upper surface may be formed. Each of the preliminary lead electrodes may include a seed pattern (e.g., the first seed pattern SL1, the second seed pattern SL2, the third seed pattern SL3, or the fourth seed pattern SL4) and a conductive layer (e.g., the first conductive layer CL1, the second conductive layer CL2, the third conductive layer CL3, or the fourth conductive layer CL4).

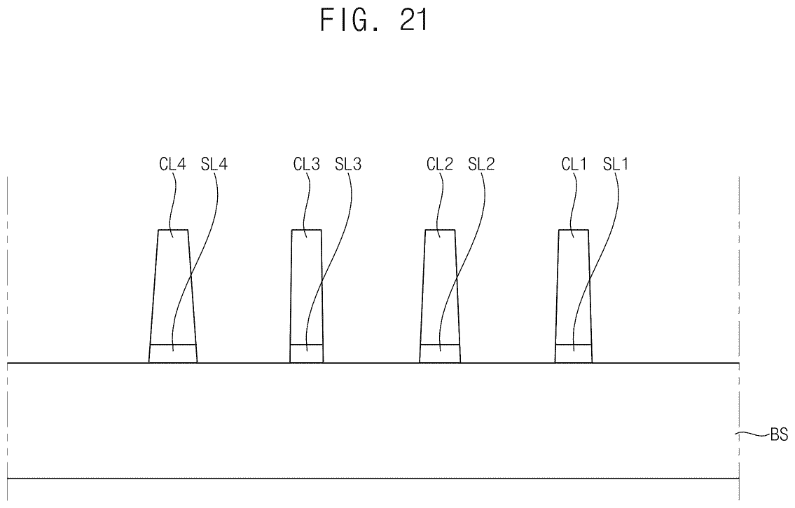

Referring to FIG. 21, in an embodiment of a method of the manufacturing the circuit board, the photoresist patterns PRP may be removed.

Referring to FIG. 22, in an embodiment of a method of the manufacturing the circuit board, a first cover layer CV1 covering the first seed pattern SL1 and the first conductive layer CL1, a second cover layer CV2 covering the second seed pattern SL2 and the second conductive layer CL2, a third cover layer CV3 covering the third seed pattern SL3 and the third conductive layer CL3, and a fourth cover layer CV4 covering the fourth seed pattern SL4 and the fourth conductive layer CL4 may be formed. The first, second, third, and fourth cover layers CV1, CV2, CV3, and CV4 may be formed through plating. In an embodiment, the first, second, third, and fourth cover layers CV1, CV2, CV3, and CV4 may include gold (Au). However, embodiments of the present disclosure are not necessarily limited thereto.

As the first, second, third, and fourth cover layers CV1, CV2, CV3, and CV4 are formed, the first lead group LG1′ including a first lead electrode including the first seed pattern SL1, the first conductive layer CL1, and the first cover layer CV1, the second lead group LG2′ including a second lead electrode including the second seed pattern SL2, the second conductive layer CL2, and the second cover layer CV2, the third lead group LG3′ including a third lead electrode including the third seed pattern SL3, the third conductive layer CL3, and the third cover layer CV3, and the fourth lead group LG4′ including a fourth lead electrode including the fourth seed pattern SL4, the fourth conductive layer CL4, and the fourth cover layer CV4 may be formed.

Accordingly, the circuit board CB′ shown in FIG. 17 may be manufactured.

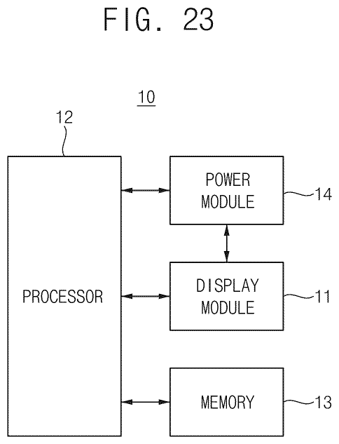

FIG. 23 is a block diagram showing an electronic device according to embodiments of the present disclosure.

Referring to FIG. 23, an embodiment of an electronic device 10 may include a display module 11, a processor 12, a memory 13, and a power module 14.

A display device according to embodiments (e.g., the display device DD of FIG. 1) may be applied to various electronic devices 10. The electronic device 10 may include the display device described above, and may further include modules or devices with additional functions other than the display device.

The processor 12 may include at least one selected from a central processing unit (CPU), an application processor (AP), a graphic processing unit (GPU), a communication processor (CP), an image signal processor (ISP), and a controller.

The memory 15 may store data information to be used for the operation of the processor 12 or the display module 11. When the processor 12 executes the application stored in the memory 15, an image data signal and/or an input control signal may be transmitted to the display module 11, and the display module 11 may process the received signal and output image information through a display screen. That is, the processor 12 may control the display module 11.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. In an embodiment, for example, the display device may include the display module 11, and the processor 12, the memory 13, and the power module 14 may be provided in the form of other devices within the electronic device 10 other than the display device. In such an embodiment, the processor 12 may provide the image data signal and the input control signal to the display device to control the display device.

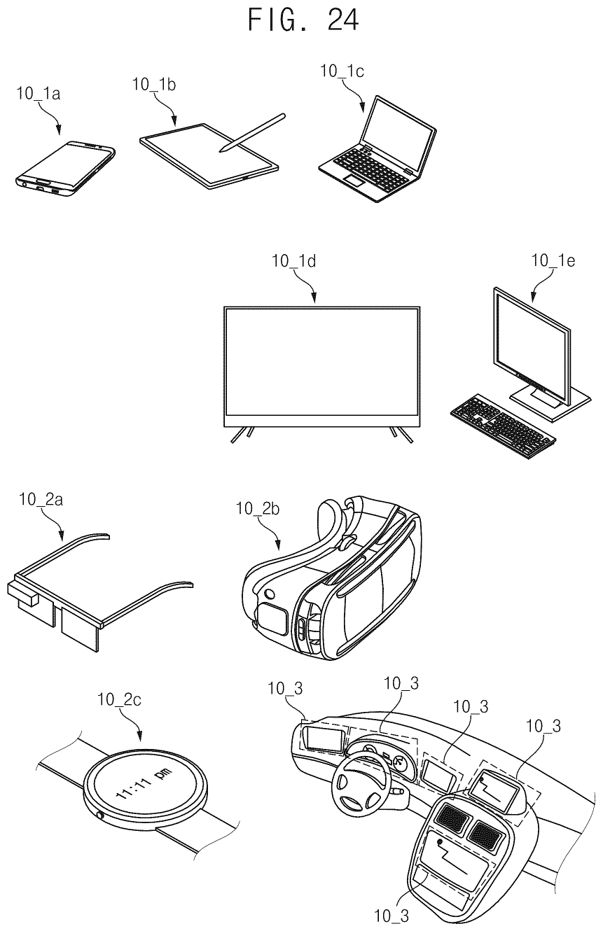

FIG. 24 is a schematic diagram showing an electronic device according to various embodiments.

Referring to FIGS. 23 and 24, various electronic devices 10 to which display devices according to the embodiments (e.g., the display device DD of FIG. 1) are applied may include not only image display electronic devices such as a smartphone 10_1a, a tablet PC 100_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

The present disclosure can be applied to various display devices, for example, display devices for vehicles, ships and aircraft, portable communication devices, display devices for exhibition or information transmission, medical display devices, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

1. A display device comprising:
a substrate including a display area and a pad area adjacent to the display area;
a plurality of pixels arranged in the display area;
a plurality of signal pads arranged in the pad area and spaced apart from each other; and
a circuit board connected to the pad area,
wherein the circuit board includes:
a base film; and
a plurality of lead electrodes arranged to be spaced apart from each other on the base film, connected one-to-one with the signal pads, and grouped into a plurality of leads groups having different thicknesses.

2. The display device of claim 1, wherein the signal pads are grouped into a plurality of pad groups, and
a pitch between the signal pads included in one of the pad groups is different from a pitch between the signal pads included in another one of the pad groups.

3. The display device of claim 2, wherein the lead groups include:
a first lead group including first lead electrodes each having a first thickness;
a second lead group including second lead electrodes each having a second thickness;
a third lead group including third lead electrodes each having a third thickness; and
a fourth lead group including fourth lead electrodes each having a fourth thickness,
the first thickness, the second thickness, the third thickness, and the fourth thickness are different from each other.

4. The display device of claim 3, wherein the pad groups include:
a first pad group including first signal pads spaced apart from each other at a first pitch and connected to the first lead group;
a second pad group including second signal pads spaced apart from each other at a second pitch and connected to the second lead group;
a third pad group including third signal pads spaced apart from each other at a third pitch and connected to the third lead group; and
a fourth pad group including fourth signal pads spaced apart from each other at a fourth pitch and connected to the fourth lead group,
the first pitch, the second pitch, the third pitch, and the fourth pitch are different from each other.

5. The display device of claim 4, wherein the fourth pitch is greater than the second pitch, the second pitch is greater than the first pitch, and the first pitch is greater than the third pitch.

6. The display device of claim 5, wherein the third thickness is greater than the first thickness, the first thickness is greater than the second thickness, and the second thickness is greater than the fourth thickness.

7. The display device of claim 6, wherein the first pad group is located at a center portion of the pad area, the second pad group is located between the first pad group and the third pad group, the third pad group is located between the second pad group and the fourth pad group, and the fourth pad group is located at an edge portion of the pad area.

8. The display device of claim 3, wherein a signal applied to the first lead group, a signal applied to the second lead group, a signal applied to the third lead group, and a signal applied to the fourth lead group are different from each other.

9. The display device of claim 1, wherein each of the lead electrodes includes:
a first conductive layer arranged on the base film and including metal;
a second conductive layer arranged on the first conductive layer and including metal; and
a cover layer covering the first and second conductive layers and including gold (Au).

10. The display device of claim 9, wherein the circuit board further includes:
a seed layer arranged to extend continuously between the base film and the lead electrodes and including metal.

11. A display device comprising:
a substrate including a display area and a pad area adjacent to the display area;
a plurality of pixels arranged in the display area;
a plurality of signal pads arranged in the pad area and spaced apart from each other; and
a circuit board connected to the pad area,
wherein the circuit board includes:
a base film; and
a plurality of lead electrodes arranged to be spaced apart from each other on the base film, connected one-to-one with the signal pads, and grouped into a plurality of leads groups,
wherein a ratio of a width of a lower surface to a width of an upper surface of each of the lead electrodes included in one lead group of the lead groups is different from a ratio of a width of lower a surface to a width of an upper lower surface of each of the lead electrodes included in another lead group of the lead groups.

12. The display device of claim 11, wherein the signal pads are grouped into a plurality of pad groups, and
a pitch between the signal pads included in one pad group of the pad groups is different from a pitch between the signal pads included in another pad group of the pad groups.

13. The display device of claim 12, wherein the lead groups include:
a first lead group including first lead electrodes;
a second lead group including second lead electrodes;
a third lead group including third lead electrodes; and
a fourth lead group including fourth lead electrodes,
a width of a first lower surface to a width of a first upper surface of each of the first lead electrodes has a first ratio, a width of a second lower surface to a width of a second upper surface of each of the second lead electrodes has a second ratio, a width of a third lower surface to a width of a third upper surface of each of the third lead electrodes has a third ratio, and a width of a fourth lower surface to a width of a fourth upper surface of each of the fourth lead electrodes has a fourth ratio, and
the first ratio, the second ratio, the third ratio, and the fourth ratio are different from each other.

14. The display device of claim 13, wherein the first lower surface, the second lower surface, the third lower surface, and the fourth lower surface are directly contact the base film.

15. The display device of claim 13, wherein the pad groups include:
a first pad group including first signal pads spaced apart from each other at a first pitch and connected to the first lead electrodes of the first lead group, respectively;
a second pad group including second signal pads spaced apart from each other at a second pitch and connected to the second lead electrodes of the second lead group, respectively;
a third pad group including third signal pads spaced apart from each other at a third pitch and connected to the third lead electrodes of the third lead group, respectively; and
a fourth pad group including fourth signal pads spaced apart from each other at a fourth pitch and connected to the fourth lead electrodes of the fourth lead group, respectively, and
the first pitch, the second pitch, the third pitch, and the fourth pitch are different from each other.

16. The display device of claim 15, wherein the fourth pitch is greater than the second pitch, the second pitch is greater than the first pitch, and the first pitch is greater than the third pitch.

17. The display device of claim 16, wherein the fourth ratio is greater than the second ratio, the second ratio is greater than the first ratio, and the first ratio is greater than the third ratio.

18. The display device of claim 17, wherein the first pad group is located at a center portion of the pad area, the second pad group is located between the first pad group and the third pad group, the third pad group is located between the second pad group and the third pad group, and the fourth pad group is located at an edge portion of the pad area.

19. The display device of claim 11, wherein each of the lead electrodes includes:
a seed pattern arranged on the base film and including metal;
a conductive layer arranged on the seed pattern and including metal; and
a cover layer covering the seed pattern and the conductive layer, and including gold (AU).

20. An electronic device comprising:
a display device; and
a processor which controls an operation of the display device,
wherein the display device includes:
a substrate including a display area and a pad area adjacent to the display area;
a plurality of pixels arranged in the display area;
a plurality of signal pads arranged in the pad area and spaced apart from each other; and
a circuit board connected to the pad area,
wherein the circuit board includes:
a base film; and
a plurality of lead electrodes arranged to be spaced apart from each other on the base film, connected one-to-one with the signal pads, and grouped into a plurality of leads groups having different thicknesses.
